(19) United States
(12) Patent Application Publication
(10) Pub. No.: US 2015/0127887 A1
(43) Pub. Date: May 7, 2015

(54) DATA STORAGE SYSTEM AND OPERATING METHOD THEREOF

(71) Applicant: SK hynix Inc., Gyeonggi-do (KR)

(72) Inventors: Tae Hoon KIM, Gyeonggi-do (KR); Joong Seob YANG, Gyeonggi-do (KR)

(73) Assignee: SK hynix Inc., Gyeonggi-do (KR)

(21) Appl. No.: 14/266,332

(22) Filed: Apr. 30, 2014

(30) Foreign Application Priority Data
Nov. 7, 2013 (KR) 10-2013-0134865

(51) Int. Cl. G11C 29/52; G06F 12/02

(52) U.S. Cl. CPC G11C 29/52; G06F 12/0246; G06F 2212/7201; G06F 2212/7205
USPC 711/103

(57) ABSTRACT

An operating method of a data storage system may include detecting a sudden power-off during a program operation on pages in a memory block, identifying a dummy program target page in the memory block when power is on after the sudden power-off, and performing the program operation on the dummy program target page using dummy data, and performing the program operation on pages in the memory block subsequent to the dummy program target page using normal data.

### CROSS-REFERENCE TO RELATED APPLICATION

The present application claims priority to Korean patent application number 10-2013-0134865, filed on Nov. 7, 2013, the entire disclosure of which is incorporated herein in its entirety by reference.

### BACKGROUND

1. Field of Invention

Various exemplary embodiments of the present invention relate generally to an electronic device, and more particularly, to a data storage system and an operating method thereof.

2. Description of Related Art

Semiconductor memory devices, among semiconductor devices included in a data storage system, may be classified into volatile memory devices and non-volatile memory devices.

The volatile memory device performs read and write operations with high speed, but the stored data is lost when the power is cut off. The non-volatile memory device performs read and write operations with relatively lower speed, but the stored data is retained even when the power is cut off. Therefore, the non-volatile memory device is used to store data that is to be maintained regardless of power supply. Examples of the non-volatile memory device include a read only memory (ROM) device, a programmable ROM (PROM) device, an electrically programmable ROM (EPROM) device, an electrically erasable and programmable ROM (EEPROM) device, a flash memory device, a phase-change RAM (PRAM) device, a magnetic RAM (MRAM) device, a resistive RAM (RRAM) device, a ferroelectric RAM (FRAM) device, or the like. The Flash memory device is typically divided into a NOR device and a NAND device.

The flash memory device enjoys the advantages of both RAM and ROM devices. For example, the flash memory device can be freely programmed and erased, which is similar to the RAM device. Further, the flash memory device can retain the stored data even when it is not powered, which is similar to the ROM device. The flash memory device has been widely used as the storage media of portable electronic devices such as mobile phones, digital cameras, personal digital assistants (PDAs), and MP3 players.

The data storage system is preferable to have high data reliability.

### SUMMARY

Exemplary embodiments of the present invention are directed to a data storage system having high data reliability and an operating method thereof. An operating method of a data storage system according to an embodiment of the present invention may include detecting a sudden power-off during a program operation on pages in a memory block, identifying a dummy program target page in the memory block when power is on after the sudden power-off, and performing the program operation on the dummy program target page using dummy data, and performing the program operation on pages in the memory block subsequent to the dummy program target page using normal data.

The dummy data may be invalid data.

The dummy data may be randomized data.

The operating method may further include re-programming a re-program page with original data. The re-program page is being programmed using the original data at the time of the sudden power-off.

A data storage system according to another embodiment of the present invention may include a semiconductor device suitable for performing a program operation on pages of a memory block and a controller suitable for detecting a sudden power-off during the program operation, identifying a dummy program target page in the memory block when power is on after the sudden power-off, and allowing the semiconductor device to perform the program operation on the dummy program target page using dummy data, and on pages in the memory block, subsequent to the dummy program target page using normal data.

The controller may include a sudden power-off detection unit suitable for generating a detection signal when power is on after the sudden power-off, and a page detection unit suitable for identifying the dummy program target page on the basis of data read out from the memory block, in response to the detection signal.

The semiconductor device may program the second page with invalid data during the dummy program operation.

The semiconductor device may program the second page with randomized data during the dummy program operation.

The controller may further allow the semiconductor device to re-program a re-program page with original data. The re-program page is being programmed using the original data at the time of the sudden power-off.

### BRIEF DESCRIPTION OF THE DRAWINGS

FIG. 1 is a block diagram illustrating a data storage system according to an embodiment of the present invention;

FIG. 2 is a block diagram illustrating a controller shown in FIG. 1;

FIG. 3 is a block diagram illustrating a semiconductor device shown in FIG. 1;

FIG. 4 is a circuit diagram illustrating a memory block shown in FIG. 3;

FIG. 5 is a flowchart illustrating an operating method of a data storage system according to an embodiment of the present invention;

FIGS. 6 to 9 are detailed flowcharts illustrating the operating method shown in FIG. 5;

FIG. 10 is a flowchart illustrating a page detection operation shown in FIG. 9;

FIG. 11 is a view of a single level cell (SLC) illustrating an operating method of a data storage system according to an embodiment of the present invention;

FIG. 12 is a block diagram illustrating a controller shown in FIG. 1;

FIG. 13 is a schematic block diagram illustrating a fusion memory device or a fusion memory system adopting the aforementioned embodiments of the present invention; and

FIG. 14 is a schematic block diagram illustrating a computing system including a semiconductor device according to an embodiment of the present invention.

### DETAILED DESCRIPTION

Hereinafter, various exemplary embodiments of the present invention will be described in detail with reference to the accompanying drawings. The figures are provided to enable those of ordinary skill in the art to make and use the present invention according to the exemplary embodiments. Throughout the disclosure, reference numerals correspond directly to the like numbered parts in the various figures and embodiments of the present invention. In addition, a singular form may include a plural form as long as it is not specifically mentioned in a sentence.

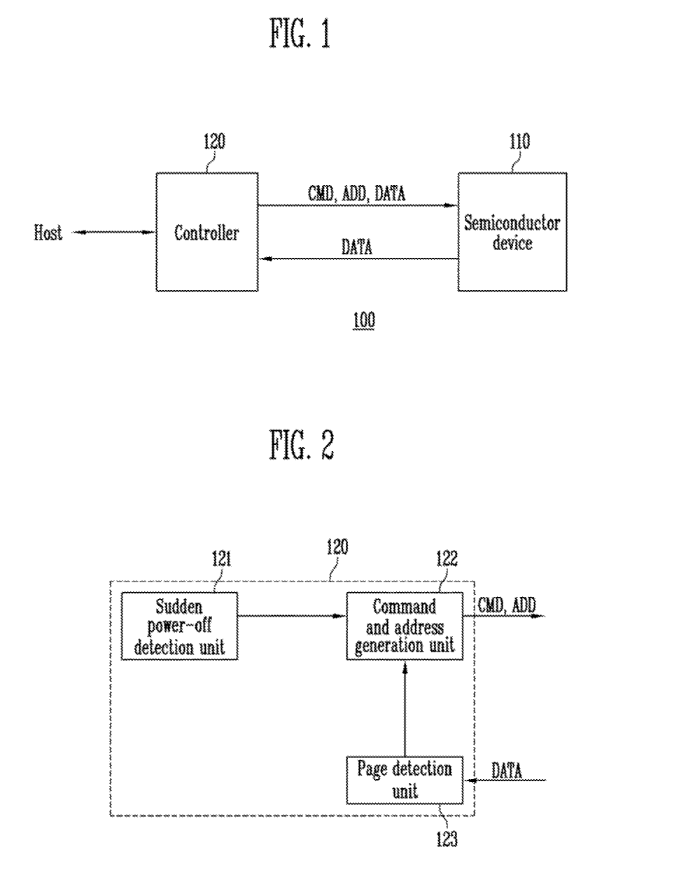

FIG. 1 is a block diagram illustrating a data storage system according to an embodiment of the present invention.

Referring to FIG. 1, a data storage system 100 may include a semiconductor device 110 and a controller 120. The controller 120 may control operations of the semiconductor device 110 in response to a request from a host.

The semiconductor device 110 may perform a program operation or a read operation on memory cells of pages included in a memory block in response to a command CMD and an address ADD from the controller 120. The semiconductor device 110 may program memory cells of a program target page with data DATA, which is input from the controller 120, and output the data DATA, read from the memory cells, to the controller 120.

When power is on after a sudden power-off occurs during a program operation on a first page as the program target page, the controller 120 may generate the command CMD and the address ADD so that the semiconductor device 110 may perform a dummy program operation on a second page, which is originally subject to the program operation after the first page if there is not the sudden power-off, and perform the program operation on a third page, which is subject to the program operation after the second page, on the basis of data read from pages. In the description, it is assumed that the program operation is originally performed on the first, second, and third page in order.

The controller 120 may generate the command CMD and the address ADD so that the semiconductor device 110 may re-program the first page with original data for the first page at the time of the sudden power-off.

According to an embodiment, the semiconductor device 110 may program the second page with invalid data during the dummy program operation.

According to an embodiment, the semiconductor device 110 may program the second page with randomized data during the dummy program operation.

According to an embodiment, the semiconductor device 110 may store one-bit data in memory cells of the first to third pages during the program operation and the dummy program operation.

FIG. 2 is a block diagram illustrating a controller shown in FIG. 1.

Referring to FIG. 2, the controller 120 may include a sudden power-off detection unit 121, a command and address generation unit 122 and a page detection unit 123.

The sudden power-off detection unit 121 may detect a sudden power-off occurring in the data storage system 100 and generate a detection signal when the data storage system 100 is powered on again after the sudden power-off.

The command and address generation unit 122 may generate the command CMD and the address ADD in response to the detection signal from the sudden power-off detection unit 121 to perform a read operation or a read scan operation on a memory block on which the program operation is stopped due to the sudden power-off. It is assumed that a first page is being programmed at the time of the sudden power-off.

The page detection unit 123 may detect a program target page or a second page, which is originally subject to the program operation after the first page, and on which the dummy program operation is performed after the sudden power-off, among the pages of the memory block, on which the program operation is stopped due to the sudden power-off, on the basis of data read from the semiconductor device 110 by the read scan operation. As another example, the page detection unit 123 may detect a page, which is first identified in an erase state (hereinafter, referred to as a “first erase page”), among pages, as the program target page. For example, the second page may be the first erase page.

The command and address generation unit 122 may generate the command CMD and the address ADD so that the semiconductor device 110 may perform the dummy program operation on the second page and the program operation on the third page, which is originally subject to the program operation after the second page, on the basis of a result of detection by the page detection unit 123.

Therefore, the data storage system 100 may improve the reliability of data by programming a page, e.g., the second page, which becomes unstable due to the sudden power-off and is identified as in the erase state, with dummy data, e.g., the invalid data or the randomized data, instead of valid data.

Further, the data storage system 100 may improve the reliability of data by re-programming the page, e.g., the first page, which becomes unstable due to the sudden power-off and is identified as in the program state, with original data for the first page at the time of the sudden power-off.

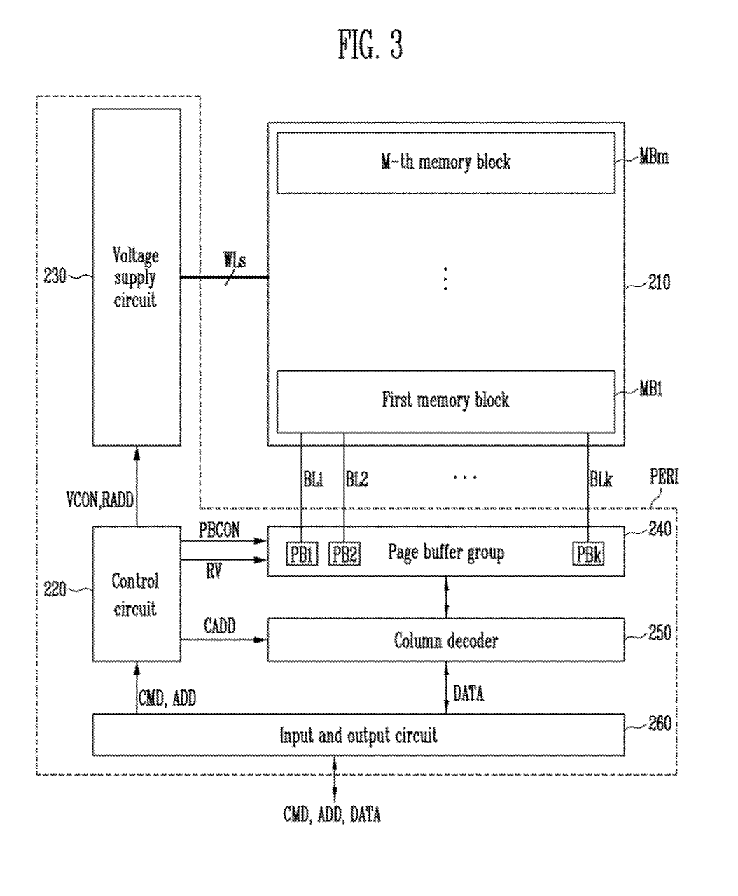

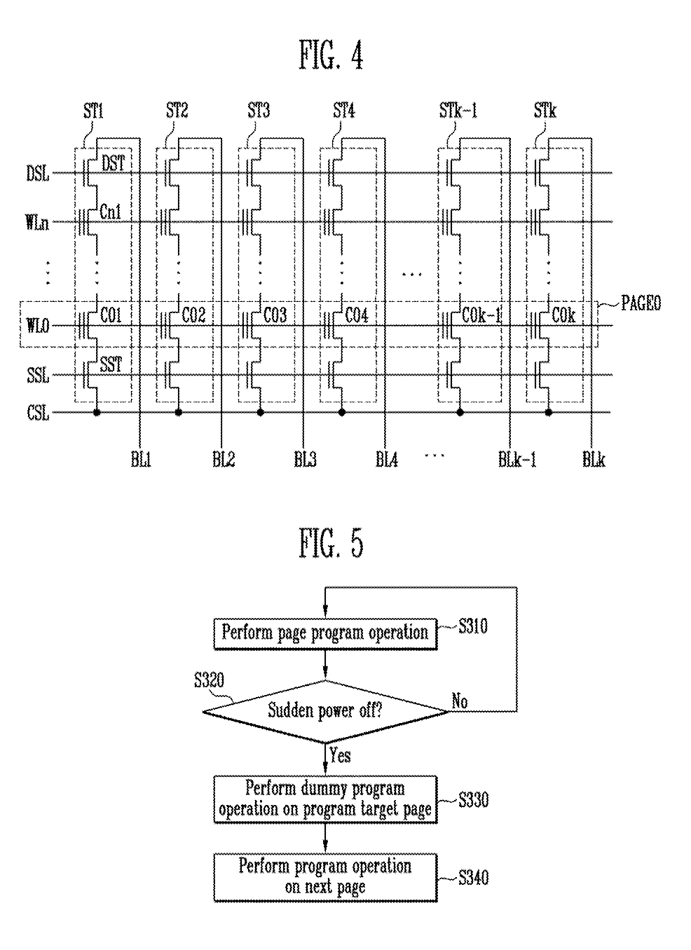

FIG. 3 is a block diagram illustrating the semiconductor device shown in FIG. 1. FIG. 4 is a circuit diagram illustrating the memory block shown in FIG. 3.

Referring to FIG. 3, a semiconductor memory device according to an embodiment of the present invention may include a memory array 210 and a peripheral circuit PERI. The memory array 210 may include first to m-th memory blocks MB1 to MBm. The peripheral circuit PERI may perform a program operation and a read operation on memory cells included in a selected page of the memory blocks MB1 to MBm. The peripheral circuit PERI may include a control circuit 220, a voltage supply circuit 230, a page buffer group 240, a column decoder 250 and an input/output circuit 260.

Referring to FIG. 4, each of the memory blocks may include a plurality of strings ST1 to STk coupled between bit lines BL1 to BLk and a common source line CSL. In other words, the strings ST1 to STk may be coupled to the bit lines BL1 to BLk, respectively, and coupled in common to the common source line CSL. Each of the strings, for example, the string ST1 may include a source select transistor SST including a source coupled to the common source line CSL, a plurality of memory cells C01 to Cn1, and a drain select transistor DST including a drain coupled to the bit line BL1. The memory cells C01 to Cn1 may be coupled in series between the select transistors SST and DST. A gate of the source select transistor SST may be coupled to a source selection line SSL. Gates of the memory cells C01 to Cn1 may be coupled to the word lines WL0 to WLn, respectively. A gate of the drain select transistor DST may be coupled to a drain selection line DSL.

Memory cells included in a memory block may be divided into a physical page unit or a logical page unit. For example, the memory cells C01 to C0k coupled to a single word line (e.g., WL0) may form a single physical page PAGE0. This page may be a basic unit for a program operation or a read operation.

The control circuit 220 may output a voltage control signal VCON to generate voltages for a program operation or a read operation in response to the command CMD which is input through the input/output circuit 260 from an exterior source. The control circuit 220 may output a PB control signal PBCON to control the page buffers PB1 to PBk included in the page buffer group 240 according to types of operations. In addition, the control circuit 220 may output a row address signal RADD and a column address signal CADD in response to an address signal ADD which is input from an exterior source through the input/output circuit 260. As an example, the control circuit 220 may output a PB control signal PBCON in order to program the invalid data when a dummy program operation is performed in response to the command CMD. As another example, the control circuit 220 may output a random value RV to the page buffers PB1 to PBk, which are included in the page buffer group 240, in order to program the randomized data when the dummy program operation is performed.

The voltage supply circuit 230 may provide operating voltages for a program operation and a read operation of memory cells to local lines including the drain selection line DSL, the word lines WL0 to WLn and the source selection line SSL of a selected memory block in response to the voltage control signal VCON of the control circuit 220. The voltage supply circuit 230 may include a voltage generator and a row decoder.

The voltage generator may output the operating voltages for the program operation or the read operation of the memory cells to the global lines in response to the voltage control signal VCON from the control circuit 220.

The row decoder may couple the global lines to the local lines DSL, WL0 to WLn, and SSL in response to the row address signals RADD of the control circuit 220 so that the operating voltages output to the global lines from the voltage generator may be transferred to the local lines DSL, WL0 to WLn, and SSL of the selected memory block in the memory array 210.

The page buffer group 240 may include a plurality of page buffers PB1 to PBk coupled to the memory array 210 through the bit lines BL1 to BLk, respectively. The page buffers PB1 to PBk of the page buffer group 240 may selectively precharge the bit lines BL1 to BLk according to data being input in order to store the data in the memory cells C01 to C0k, or may sense voltages of the bit lines BL1 to BLk in order to read data from the memory cells in response to the PB control signal PBCON from the control circuit 220. The page buffer group 240 may randomize the data being input and store the randomized data in the memory cells C01 to C0k on the basis of the random value RV from the control circuit 220 in order to program the randomized data during a dummy program operation. According to an embodiment, the semiconductor device may include a separate randomizer, instead of performing a randomize operation in the page buffer group 240.

The column decoder 250 may select the page buffers PB1 to PBk included in the page buffer group 240 in response to the column address signal CADD output from the control circuit 220. In other words, the column decoder 250 may sequentially transfer data to be stored in the memory cells to the page buffers PB1 to PBk in response to the column address signal CADD. In addition, the column decoder 250 may sequentially select the page buffers PB1 to PBk in response to the column address signal CADD so that the data of the memory cells latched to the page buffers PB1 to PBk by the read operation may be output to the exterior.

The input/output circuit 260 may transfer the data, input from the exterior, to the column decoder 250 in response to control of the control circuit 220 in order to input the data to the page buffer group 240 so that the data may be stored in the memory cells during the program operation. When the column decoder 250 transfers the data, transferred from the input/output circuit 260, to the page buffers PB1 to PBk of the page buffer group 240, the page buffers PB1 to PBk may store the input data to an internal latch circuit. In addition, the input/output circuit 260 may output the data, transferred from the page buffers PB1 to PBk of the page buffer group 240 through the column decoder 250, to the exterior during a read operation.

FIG. 5 is a flowchart illustrating an operating method of a data storage system according to an embodiment of the present invention.

Referring to FIG. 5, according to an embodiment of the present invention, a program operation may be performed on pages of a memory block at step S310. The program operation may be sequentially performed on the pages from a start page to an end page.

During the program operation, it may be checked whether or not the sudden power-off occurs in the data storage system 100 at step S320. When the sudden power-off is detected by the sudden power-off detection unit 121 and the data storage system 100 is powered on again after the sudden power-off occurs, the dummy program operation at step S330 may be performed on the program target page, e.g., the second page in the above described example, among the pages of the memory block, on which the program operation is stopped by the sudden power-off.

Subsequently, the program operation at step S340 may be performed on a page, e.g., the third page in the above described example, subsequent to the dummy programmed page or the second page.

According to an embodiment, one-bit data may be stored in the memory cells during the program operation.

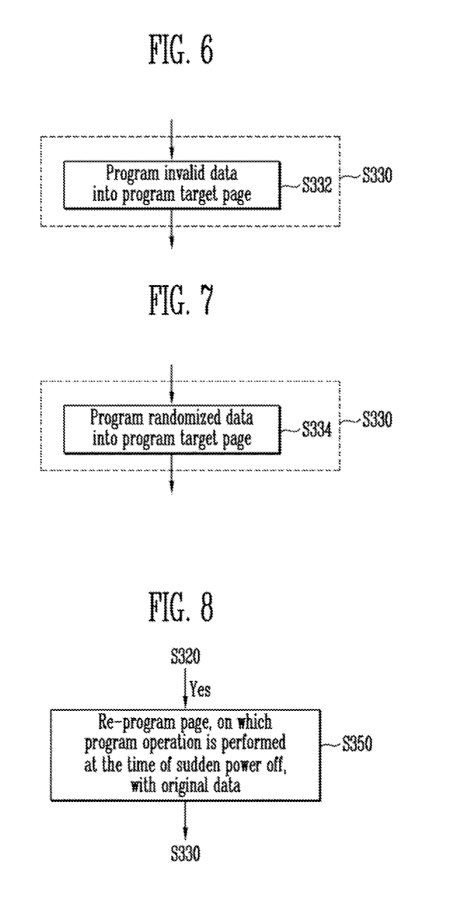

FIGS. 6 to 9 are detailed flowcharts illustrating the operating method illustrated in FIG. 5.

With reference to FIGS. 6 and 7, the dummy program operation of step S330 may be performed on the program target page after the sudden power-off with the invalid data or the randomized data at steps S332 and S334.

Therefore, the reliability of data may be improved by programming a page, e.g. the second, which becomes unstable due to the sudden power-off and is identified as being in the erase state, with the invalid data or the randomized data as dummy data.

Referring to FIG. 8, between the steps S320 and S330, the operating method of the data storage system may further include step 350 of re-programming a page, e.g. the first page, on which a program operation is being performed at the time of the sudden power-off, and which becomes unstable due to the sudden power-off and is identified as in the program state, with original data for the page at the time of the sudden power-off.

In the case of a single-level cell that stores one bit and guarantees the number of programs per page, it is possible to program parts of a page at different times as well as to program a page repeatedly with the same data.

Therefore, the reliability of data may be improved by re-programming the first page, which becomes unstable due to the sudden power-off and is identified as in the program state, with the original data.

Referring again to FIG. 9, between the steps S320 and S330, the operating method of the data storage system may further include step 410 of detecting the first erase page, which is first identified as in an erase state, among the pages of the memory block, on which the program operation is stopped due to the sudden power-off.

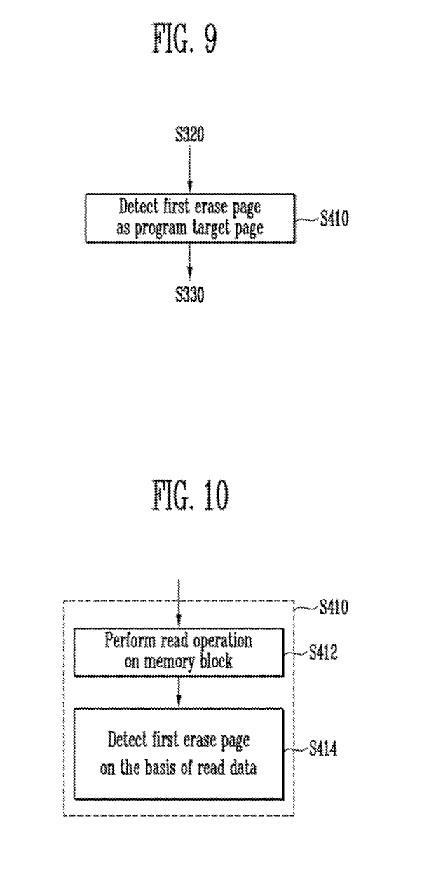

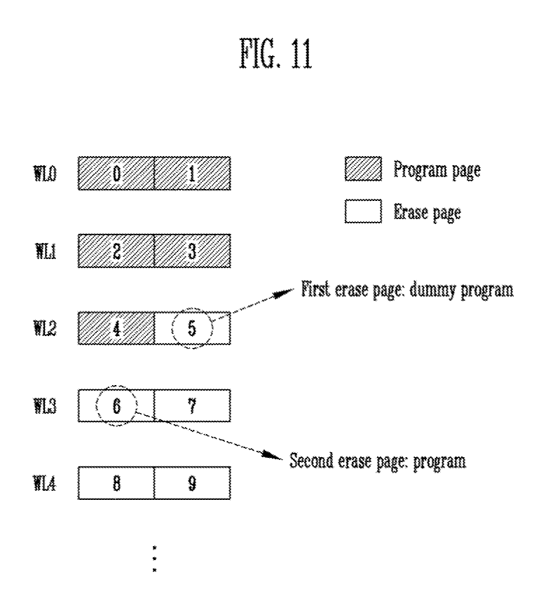

FIG. 10 is a flowchart illustrating the step S410 of page detection shown in FIG. 9.

Referring to FIG. 10, in step 410 of detecting the first erase page, which is first identified as in the erase state, among the pages of the memory block, on which the program operation is stopped due to the sudden power-off, the read operation or the read scan operation may be performed on the memory block, on which the program operation is stopped due to the sudden power-off, at step S412.

Subsequently at step S414, the first erase page may be detected among the pages identified as in the erase state on the basis of read data.

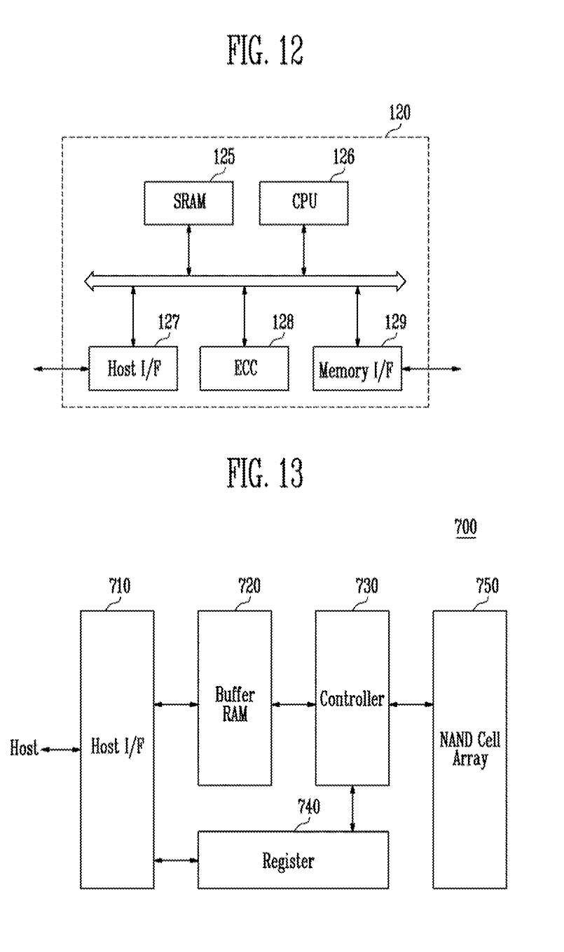

FIG. 11 is a diagram of the single-level cell (SLC) illustrating the operating method of the data storage system according to an embodiment of the present invention.

For example, in FIG. 11, it is assumed that operations may be performed separately on even memory cells and odd memory cells of the SLC, among memory cells coupled to a single word line. However, this example is shown for the convenience of illustration. The embodiment of the present invention may also be applied to simultaneous operation on the even memory cells and the odd memory cells, which are SLCs or multi-level cells MLCs.

The reference numbers 0 to 9 of pages shown in FIG. 11 may refer to the order of the program operation performed on the pages.

FIG. 11 shows programmed pages 0 to 4 and erase pages 5 to 9, on which the program operation is not performed. It is assumed that the sudden power-off occurs while the program operation is being performed on page 4. Then page 5 may be the program target page, on which the dummy program operation is to be performed after the sudden power-off, or the first erase page, which is first identified as in the erase state, among pages.

Page 5 may be unstable due to the sudden power-off that occurs while the program operation is being performed on page 4. Therefore, the dummy program operation may be performed on page 5 in order to improve the reliability of data. During the dummy program operation Page 5 may be programmed with the invalid data or the randomized data (in which ‘0’ and ‘1’ are mixed).

Therefore, the reliability of data may be improved by programming the page, e.g., the second page or page 5, which becomes unstable due to the sudden power-off and is identified as in the erase state, with the invalid data or the randomized data as dummy data.

In addition, page 4 may be re-programmed with the original data for page 4 at the time of the sudden power-off.

Therefore, the reliability of data may be improved by re-programming a page, e.g., the first page or page 4, which becomes unstable due to a sudden power-off and is identified as in the program state, with the original data for the page at the time of the sudden power-off.

FIG. 12 is a detailed diagram illustrating the controller shown in FIG. 1.

The data storage system 100, show in FIG. 1, may be a solid state disk (SSD) or a memory card in which the semiconductor device 110 and the controller 120 are combined.

Referring to FIG. 12, the controller 120 may include SRAM 125, a processing unit (CPU) 126, a host interface 127, an error correcting code block (ECC) 128 and a memory interface 129. The SRAM 125 may function as an operation memory of the CPU 126. The host interface 127 may include a data exchange protocol of a host being coupled to the data storage system 100. For example, when the memory system 100 is an SSD, the memory controller 110 may communicate with an external device (e.g., a host) through one of the interface protocols including USB, MMC, PCI-E, SATA, PATA, SCSI, ESDI and IDE.

The ECC 128 may detect and correct errors included in data read from the semiconductor device 110. The memory interface 129 may interface with the semiconductor device 110. The CPU 126 may perform the general control operation for data exchange of the controller 120.

Though not shown in FIG. 12, the data storage system 100 may further include ROM (not shown) that stores code data to interface with the host. The semiconductor device 110 may be a multi-chip package composed of a plurality of flash memory chips. The data storage system 100 may be provided as a storage medium having high reliability and low error rate. The semiconductor device according to an embodiment of the present invention may be provided in a memory system such as the semiconductor disk device (a solid state disk (SSD)), a multi media card (MMC) and an eMMC (embedded multi media card) and a universal flash storage (UFS) on which research has been actively conducted.

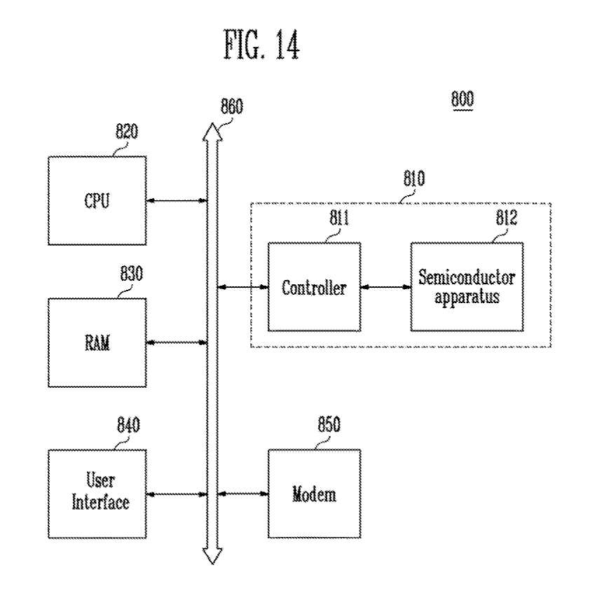

FIG. 13 is a schematic block diagram of a fusion memory device or a fusion memory system adopting the aforementioned embodiments of the present invention. For example, technical features of the present invention may be applied to a OneNand flash memory device 700 as the fusion memory device.

The OneNand flash memory device 700 may include a host interface (I/F) 710, a buffer RAM 720, a controller 730, a register 740 and a NAND flash cell array 750. The host interface 710 may exchange various types of information with a device through a different protocol. The buffer RAM 720 may have built-in codes for driving the memory device or temporarily store data. The controller 730 may control read and program operations and every state in response to a control signal and a command that are externally given. The register 740 may store data including instructions, addresses and configurations defining a system operating environment in the memory device. The NAND flash cell array 750 may include operating circuits including non-volatile memory cells and page buffers. In response to a write request from a host, the OneNAND flash memory device 700 may program data in the aforementioned manner.

FIG. 14 is a schematic block diagram of a computing system 800 including a semiconductor device according to an embodiment of the present invention.

The computing system 800 according to an embodiment of the present invention may include a microprocessor (CPU) 820, RAM 830, a user interface 840, a modem 850, such as a baseband chipset, and a memory system 810 that are electrically coupled to a system bus 860. In addition, if the computing system 800 is a mobile device, then a battery may be provided to apply operating voltages to the computing system 800. Though not shown in FIG. 14, the computing system 800 may further include application chipsets, a Camera Image Processor (CIS), or mobile DRAM. The memory system 810 may form a Solid State Drive/Disk (SSD) that uses a non-volatile memory to store data. The memory system 810 may be provided as a fusion flash memory (e.g., OneNAND flash memory).

According to a data storage system and an operating method of the data storage system, since a page, which becomes unstable due to a sudden power-off and is identified as being in an erase state, is programmed with invalid data or randomized data as dummy data, the reliability of data may be improved.

In addition, according to a data storage system and an operating method of the data storage system, since a page, which becomes unstable due to a sudden power-off and is identified as in an erase state, is re-programmed, the reliability of data may be improved.

What is claimed is:

1. An operating method of a data storage system, comprising:
detecting a sudden power-off during a program operation on pages in a memory block;
identifying a dummy program target page in the memory block when power is on after the sudden power-off, and performing the program operation on the dummy program target page using dummy data; and
performing the program operation on pages in the memory block subsequent to the dummy program target page using normal data.

2. The operating method of claim 1, wherein the dummy data is invalid data.

3. The operating method of claim 1, wherein the dummy data is randomized data.

4. The operating method of claim 1, further comprising re-programming a re-program page with original data,
wherein the re-program page is being programmed using the original data at the time of the sudden power-off.

5. The operating method of claim 1, wherein the memory block includes one or more single level memory cells.

6. The operating method of claim 1, wherein the dummy program page is a page, which is first identified as in an erase state when power is on after the sudden power-off.

7. The operating method of claim 6, wherein identifying the dummy program target page comprises:
performing a read operation on the memory block; and
detecting the page, which is first identified as in the erase state, as the dummy program target page on the basis of read data.

8. A data storage system, comprising:
a semiconductor device suitable for performing a program operation on pages of a memory block; and
a controller suitable for detecting a sudden power-off during the program operation, identifying a dummy program target page in the memory block when power is on after the sudden power-off, and allowing the semiconductor device to perform the program operation on the dummy program target page using dummy data, and on pages in the memory block subsequent to the dummy program target page using normal data.

9. The data storage system of claim 8, wherein the controller comprises:
a sudden power-off detection unit suitable for generating a detection signal when power is on after the sudden power-off; and
a page detection unit suitable for identifying the dummy program target page on the basis of data read out from the memory block, in response to the detection signal.

10. The data storage system of claim 9, wherein the page detection unit detects a page, which is first identified as in an erase state, as the dummy program target page.

11. The data storage system of claim 8, wherein the dummy data is invalid data.

12. The data storage system of claim 8, wherein the dummy data is randomized data.

13. The data storage system of claim 8, wherein the controller further allows the semiconductor device to re-program a re-program page with original data,
wherein the re-program page is being programmed using the original data at the time of the sudden power-off.

14. The data storage system of claim 8, wherein the memory block includes one or more single level memory cells.

15. An operating method of a data storage system, comprising:
detecting a sudden power-off during a first operation; and
identifying a target page(s) in the memory block, when power has returned after the sudden power-off, and performing a second operation on the target page(s), in a manner suitable for stabilizing a memory device,
wherein dummy, or invalid data is written during the second operation.

16. The operating method of a data storage system according to claim 15, further comprising: continuing to perform the first operation to a page on which the first operation is performed at the time of the sudden power-off.
